(19) United States
(12) Patent Application Publication
(10) Pub. No.: US 2008/0268660 A1
(43) Pub. Date: Oct. 30, 2008

(54) METHOD OF MANUFACTURING SEMICONDUCTOR DEVICE

(76) Inventors: Takaharu Itani, Yokohama-shi (JP); Kenichi Yoshino, Fujisawa-shi (JP); Takayuki Ito, Oita-shi (JP); Takashi Kawakami, Yokohama-shi (JP); Tetsuya Kugimiya, Kawasaki-shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 12/108,589

(22) Filed: Apr. 24, 2008

(30) Foreign Application Priority Data
Apr. 25, 2007 (JP) 2007-115024
Dec. 18, 2007 (JP) 2007-326350

(51) Int. Cl. H01L 21/02; H01L 21/00

(52) U.S. Cl. 438/795; 257/E21.002

(57) ABSTRACT

A method of manufacturing a semiconductor device that involves a heat treatment of a semiconductor substrate, has removing a superficial layer from an upper surface of an edge part of said semiconductor substrate, a bevel surface of the edge part of said semiconductor substrate and a side surface of the edge part of said semiconductor substrate; and conducting the heat treatment of said semiconductor substrate by irradiating said semiconductor substrate with light having a pulse width of 0.1 milliseconds to 100 milliseconds from a light source after said superficial layer is removed.

### CROSS-REFERENCE TO RELATED APPLICATION

This application is based upon and claims the benefit of priority from the prior Japanese Patent Application No. 2007-115024, filed on Apr. 25, 2007, and No. 2007-326350, filed on Dec. 18, 2007 the entire contents of which are incorporated herein by reference.

### BACKGROUND OF THE INVENTION

1. Field of the Invention

The present invention relates to a method of manufacturing a semiconductor device that involves heating of a semiconductor substrate with a high density light source.

2. Background Art

To improve the performance of large scale integrated (LSI) circuits, researches to increase the integration density, or in other words, to miniaturize elements constituting LSI circuits have been pursued.

Miniaturization of an element requires not only reduction of the area of the impurity diffusion region but also reduction of the depth of the diffusion region. Therefore, for example, it is important to optimize ion implantation and a subsequent heat treatment (annealing) for electrically activating the impurity when forming the impurity diffusion region, such as the source/drain region, and the functional region, such as the channel region immediately below the gate insulating film.

Impurity ions commonly used for ion implantation include a boron (B) ion, a phosphorus (P) ion and an arsenic (As) ion. These impurity ions have high diffusion coefficients in silicon (Si). Therefore, in rapid thermal annealing (RTA) using a halogen lamp, inward and outward diffusions of the impurity ions occur, and it is difficult to form a shallow impurity diffusion region.

The inward and outward diffusions can be reduced by decreasing the annealing temperature. However, if the annealing temperature is decreased, the activation rate of the impurity ion significantly decreases. As a result, the electrical resistance of the impurity diffusion region increases, and the characteristics of the semiconductor element are substantially degraded. Therefore, even if the annealing temperature is decreased, it is difficult to form a shallow impurity diffusion region having low resistance.

As described above, it has been difficult to form a shallow (20 nm or less) impurity diffusion region having low resistance by the conventional RTA using a halogen lamp.

In order to solve the problem, in recent years, as means for improving the activation rate in an extremely short time, there has been contemplated an annealing method that uses a flash lamp containing an inert gas, such as xenon (Xe). The flash lamp has a half pulse width of about 10 milliseconds. Therefore, if the flash lamp is used for annealing, the upper surface of the wafer is maintained at high temperature for an extremely short time. Therefore, if the flash lamp is used for annealing, the impurity ion-implanted into the upper surface of the wafer can be activated while preventing diffusion of the impurity.

However, the flash lamp annealing (FLA) has the following problem.

That is, in the FLA, the wafer is previously heated to about 500° C. by a heater. Then, the wafer thus heated is irradiated with light from the flash lamp, thereby heating the upper surface of the wafer to 1100° C. or higher in a short time of about 1 millisecond to 10 milliseconds.

Thus, the temperature of the upper surface of the wafer instantaneously increases from about 500° C. to 1100° C. or higher. As a result, a temperature difference occurs between the upper part and the lower part of the wafer, and the thermal stress in the wafer increases. The increased thermal stress in the wafer can cause a crystal defect or a crack in a region of an outer perimeter or inner part of the wafer having a depth of about 30 μm to 50 μm, for example.

In addition, the heat dissipation rate also differs between the inner part and the outer perimeter of the wafer, and the difference in heat dissipation rate can cause a significant thermal stress between the inner part and the outer part of the wafer. In particular, a high thermal stress is concentrated at the outer perimeter of the wafer, so that a large number of crystal defects can occur at the outer perimeter of the wafer. In addition, the thermal stress in the wafer can cause deformation of the wafer, and the force of the deformation can move the wafer on the processing table. Therefore, the edge part of the wafer is likely to collide with the sidewall of the stage, and a crack or a flaw is likely to occur.

In addition, in the course of various steps preceding the FLA process, many contact scratches (flaws) have been formed in the outer perimeter of the wafer by being gripped by a conveyer arm or by coming into contact with a wafer holding jig in the treatment apparatus.

There is a conventional method of manufacturing a semiconductor device that involves removing a superficial layer of a lower surface of a semiconductor substrate that has come into contact with a holding jig when a high temperature heat treatment is conducted (see Japanese Patent Laid-Open No. 2002-134521, for example).

According to the conventional method of manufacturing a semiconductor device, dislocations that occur during a subsequent heat treatment due to damage or dislocation caused by contact with the holding jig or the like are reduced.

### SUMMARY OF THE INVENTION

According to one aspect of the present invention, there is provided: a method of manufacturing a semiconductor device that involves a heat treatment of a semiconductor substrate, comprising:

removing a superficial layer from an upper surface of an edge part of said semiconductor substrate, a bevel surface of the edge part of said semiconductor substrate and a side surface of the edge part of said semiconductor substrate; and

conducting the heat treatment of said semiconductor substrate by irradiating said semiconductor substrate with light having a pulse width of 0.1 milliseconds to 100 milliseconds from a light source after said superficial layer is removed.

According to the other aspect of the present invention, there is provided: a method of manufacturing a semiconductor device that involves a heat treatment of a semiconductor substrate, comprising:

conducting the heat treatment of said semiconductor substrate by irradiating said semiconductor substrate with light having a pulse width of 0.1 milliseconds to 100 milliseconds from a light source; and

removing a superficial layer from an upper surface of an edge part of said semiconductor substrate, a bevel surface of the edge part of said semiconductor substrate and a side surface of the edge part of said semiconductor substrate after the heat treatment of said semiconductor substrate is conducted.

According to further aspect of the present invention, there is provided: a method of manufacturing a semiconductor device that involves a heat treatment of a semiconductor substrate, comprising:

removing a superficial layer from a lower surface of an edge part of said semiconductor substrate and a lower bevel surface of the edge part of said semiconductor substrate; and

conducting the heat treatment of said semiconductor substrate by irradiating said semiconductor substrate with light having a pulse width of 0.1 milliseconds to 100 milliseconds from a light source after said superficial layer is removed.

### BRIEF DESCRIPTION OF THE DRAWINGS

FIG. 1A is a schematic diagram showing a step in the method of manufacturing a semiconductor device according to an embodiment 1;

FIG. 1B is a schematic diagram showing a step in the method of manufacturing a semiconductor device according to an embodiment 1, is continuous from FIG. 1A;

FIG. 1C is a schematic diagram showing a step in the method of manufacturing a semiconductor device according to an embodiment 1, is continuous from FIG. 1B;

FIG. 1D is a schematic diagram showing a step in the method of manufacturing a semiconductor device according to an embodiment 1, is continuous from FIG. 1C;

FIG. 2 is a schematic enlarged cross-sectional view of an edge part of a wafer polished in the step shown in FIG. 1C;

FIG. 3 is a table showing the result of observation by X-ray topograph of wafers heated with a high density light source;

FIG. 4 is a graph showing a process margin for a wafer crack in the FLA step in the method of manufacturing a semiconductor device according to the embodiment 1;

FIG. 5 is a graph showing a process margin for a wafer crack in the FLA step in a conventional method of manufacturing a semiconductor device;

FIG. 6A is a schematic diagram showing a step in a method of manufacturing a semiconductor device according to an embodiment 2 of the present invention;

FIG. 6B is a schematic diagram showing a step in the method of manufacturing a semiconductor device according to an embodiment 2, is continuous from FIG. 6A;

FIG. 6C is a schematic diagram showing a step in the method of manufacturing a semiconductor device according to an embodiment 2, is continuous from FIG. 6B;

FIG. 6D is a schematic diagram showing a step in the method of manufacturing a semiconductor device according to an embodiment 2, is continuous from FIG. 6C;

FIG. 6E is a schematic diagram showing a step in the method of manufacturing a semiconductor device according to an embodiment 2, is continuous from FIG. 6D;

FIG. 6F is a schematic diagram showing a step in the method of manufacturing a semiconductor device according to an embodiment 2, is continuous from FIG. 6E;

FIG. 6G is a schematic diagram showing a step in the method of manufacturing a semiconductor device according to an embodiment 2, is continuous from FIG. 6F;

FIG. 6H is a schematic diagram showing a step in the method of manufacturing a semiconductor device according to an embodiment 2, is continuous from FIG. 6G;

FIG. 6I is a schematic diagram showing a step in the method of manufacturing a semiconductor device according to an embodiment 2, is continuous from FIG. 6H;

FIG. 6J is a schematic diagram showing a step in the method of manufacturing a semiconductor device according to an embodiment 2, is continuous from FIG. 6I;

FIG. 7 is a graph showing the frequencies of fractures of wafers processed by the method of manufacturing a semiconductor device according to the embodiment 2 and wafers processed by a conventional method of manufacturing a semiconductor device in the silicidation annealing step;

FIG. 8A is a schematic diagram showing a step in the method of manufacturing a semiconductor device according to an embodiment 3 of the present invention;

FIG. 8B is a schematic diagram showing a step in the method of manufacturing a semiconductor device according to the embodiment 3 of the present invention, is continuous from FIG. 8A;

FIG. 8C is a schematic diagram showing a step in the method of manufacturing a semiconductor device according to the embodiment 3 of the present invention, is continuous from FIG. 8B;

FIG. 8D is a schematic diagram showing a step in the method of manufacturing a semiconductor device according to the embodiment 3 of the present invention, is continuous from FIG. 8C; and

FIG. 9 is a schematic enlarged cross-sectional view of an edge part of a wafer polished in the step shown in FIG. 8C.

### DETAILED DESCRIPTION

If a wafer having damage (a crystal defect or a crack) a an edge part thereof is subjected to a heat treatment step following FLA, the thermal stress in the wafer increases again Even if the thermal stress slowly increases, since the mechanical strength of the wafer has been decreased at the damaged part, the wafer is easily fractured from the damage.

Thus, damage that occurs in the outer perimeter of the wafer compromises the productivity of the semiconductor device.

In addition, a crystal defect can occur in the route perimeter of the wafer in a high temperature heat treatment step preceding the FLA process.

Both the flaw and the crystal defect in the route perimeter compromise the strength of the wafer and reduce the resistance of the wafer to an internal or external force.

If such a wafer is subjected to the FLA process, the internal thermal stress abruptly increases, and the wafer can be fractured from the flaw or crystal defect in the outer perimeter.

The degree of flaw or crystal defect differs among wafers and therefore, the frequency of fractures of wafers in the FLA process also varies. However, for example, the fracture rate in about one in several hundred wafers. The fracture rate of about one in several hundred wafers poses a problem of productivity decrease because manufacturing facilities for mass production of ICs process hundreds of wafers every day.

There are problems that damage occurring in the FLA process causes fracture of a wafer in a subsequent step and that damage occurring in a preceding step causes fracture of a wafer during the FLA process.

As a solution to these problems, it can be contemplated that the power of the FLA is lowered to reduce the energy density of light irradiation. However, in this case, the impurity cannot be sufficiently activated.

However, the conventional technique (see Japanese Patent Laid-Open No. 2002-134521, for example) does not take damage to the outer perimeter (in the vicinity of the bevel) of the wafer into account and is not intended to reduce crystal defects or cracks that are problematic in the FLA process using a flash lamp or the like.

According to a method of manufacturing a semiconductor device according to an aspect of the present invention, before a heat treatment step of heating a semiconductor substrate by light irradiation, damage existing in a superficial layer of an outer perimeter (an upper surface, a bevel surface and a side surface of an edge part) of the semiconductor substrate is removed. As a result, the process window for the heat treatment step is expanded, and the frequency of fractures of substrates in the heat treatment is substantially reduced.

In addition, according to a method of manufacturing a semiconductor device according to an aspect of the present invention, after a thermal step of heating a semiconductor substrate by light irradiation, damage existing in a superficial layer of an outer perimeter (an upper surface, a bevel surface and a side surface of an edge part) of the semiconductor substrate is removed. As a result, the frequency of fractures of substrates in a subsequent heat treatment is substantially reduced.

In the following, embodiments of the present invention will be described with reference to the drawings.

### EMBODIMENT 1

A method of manufacturing a semiconductor device according to an embodiment 1 will be described. In the following, for the sake of simplicity, a configuration of one MOS transistor will be particularly described.

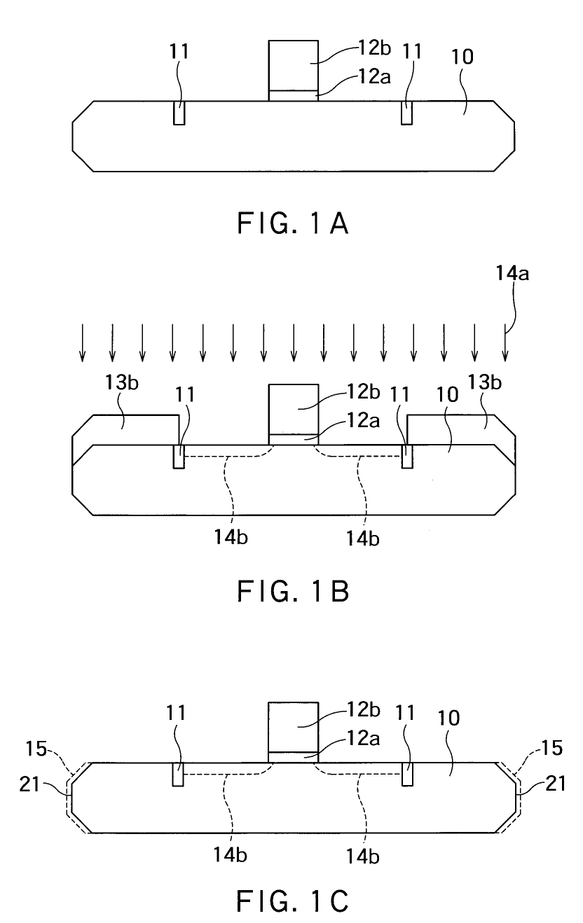

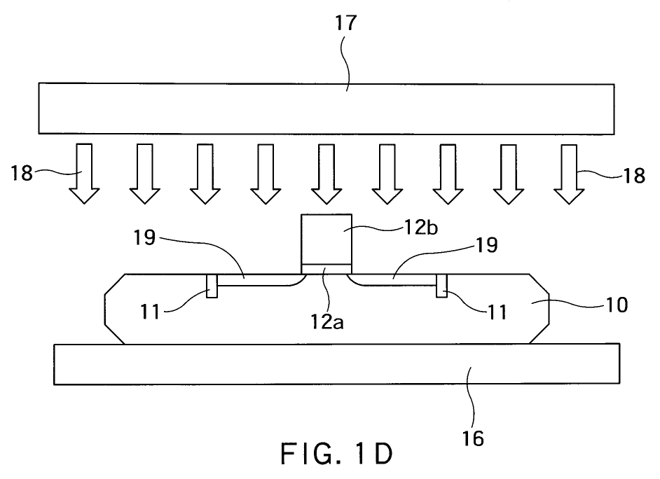

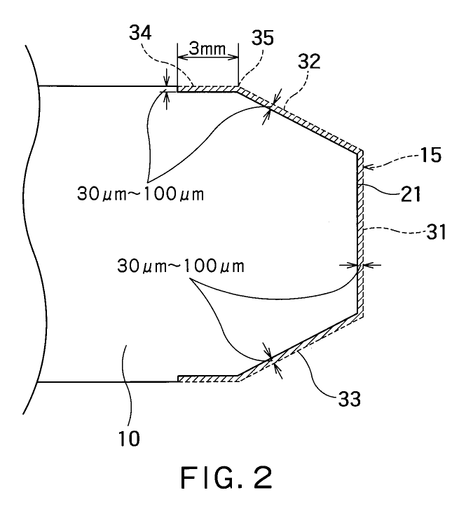

FIGS. 1A to 1D are schematic diagrams showing different steps in the method of manufacturing a semiconductor device according to the embodiment 1, which is an aspect of the present invention. FIG. 2 is a schematic enlarged cross-sectional view of an edge part of a wafer polished in the step shown in FIG. 1C.

First, as shown in FIG. 1A, a device isolation region 11, a gate insulating film 12a and a gate electrode 12b are formed on a wafer 10 of silicon or the like, which is a semiconductor substrate, by a well-known method. The wafer 10 is selected from among a bulk single crystal silicon wafer, an epitaxial wafer and a SOI wafer, for example.

Then, as shown in FIG. 1B, using the gate electrode 12b and a resist film 13b having a desired pattern formed by photolithography as a mask, an impurity ion 14a is ion-implanted into a source/drain extension region 14b formed in an upper surface of the wafer 10. After the ion implantation, the resist film 13b is removed by peeling off.

Then, as shown in FIG. 1C, an upper surface, bevel surfaces and a side surface of an edge part of the wafer 10 are polished to remove a superficial layer thereof having a thickness of about 30 μm to 100 μm. Thus, a defect, a crack or the like formed in the superficial layer of the edge part of the wafer 10 can be removed. In FIG. 1C, the dotted line 15 indicates the surface of the edge part of the wafer 10 yet to be polished (before the superficial layer is removed). The solid line 21 indicates the surface of the edge part of the wafer 10 polished (after the superficial layer is removed).

The edge part of the wafer 10 can be polished by a commonly known method. For example, the lower surface of the wafer 10 is fixed to a base material by vacuum chucking. Then, the wafer 10 is pressed against a polishing pad while rotating the wafer 10 along with the base material. In this process, a polishing liquid containing fine abrasive grains dispersed therein is supplied to the part of the wafer 10 in contact with the polishing pad. Thus, the superficial layer of the edge part of the wafer 10 in contact with the polishing pad can be removed by polishing.

The thickness of the part of the wafer removed by polishing can be estimated from the length of polishing time if the relationship between the polishing time and the amount of shavings is previously determined by measurement. In the determination of the relationship, the amount of shavings can be estimated by observing the difference between the shape of the cross section of the wafer before polishing and that after polishing with an electron microscope or the like.

As shown in FIG. 2, the wafer 10 has a side surface 31, a bevel surface 32 and a bevel surface 33 at the edge part thereof.

In FIG. 2, the shaded part indicates the superficial layer of the edge part of the wafer 10 that is removed by polishing. In this embodiment, as described above, the thickness of the superficial layer removed from an upper surface 34, the bevel surfaces 32 and 33 and the side surface 31 of the edge part of the wafer 10 falls within a range of 30 μm to 100 μm.

Thus, damage, such as a flaw, a crack and a crystal defect, that can exist in the upper surface 34, the bevel surfaces 32 and 33 and the side surface 31 of the edge part can also be removed. Therefore, FLA can be conducted without causing degradation of the strength of the wafer 10 due to such damage.

In some cases, an extremely fine stripe pattern can be formed on the polished surface of the edge part of the wafer 10. This pattern is a trace of an abrasive grain. However, the trace is an extremely shallow groove, and therefore it can be considered that the trace have no effect on the strength of the wafer 10.

In addition, as shown in FIG. 2, a lower surface of the edge part of the wafer 10 can also be polished. In this case, damage, such as a flaw, a crack and a crystal defect, in the lower surface of the edge part of the wafer 10 can also be removed.

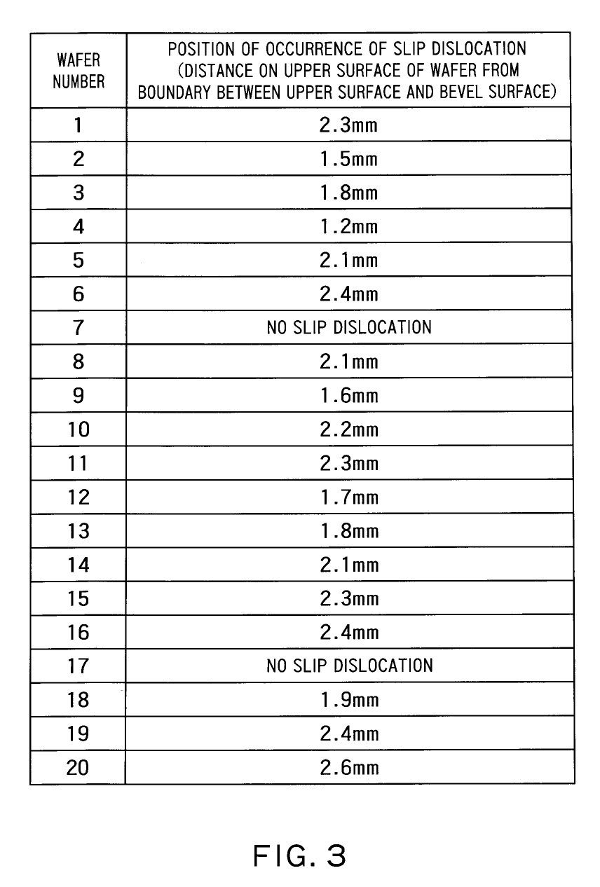

FIG. 3 is a table showing the result of observation by X-ray topograph of wafers heated with a high density light source.

From FIG. 3, it can be considered that slip dislocations that occur in the vicinity of the bevel tend to concentratedly occur in a region extending 1 mm to 3 mm inwardly from the boundary between the upper surface and the bevel surface of the wafer.

Therefore, as shown in FIG. 2, the superficial layer of the upper surface 34 of the edge part of the wafer 10 is removed over a region extending 3 mm from a boundary 35 between the upper surface 34 and the bevel surface 32 of the edge part of the wafer 10. Thus, occurrence of a slip dislocation in the vicinity of the bevel can be suppressed.

In an experiment conducted for wafers having different diameters, such as 200 mm and 300 mm, polishing the region extending 3 mm inwardly from the boundary between the upper surface and the bevel surface of the wafer was sufficient to suppress occurrence of slip dislocations in the vicinity of the bevel.

Then, a FLA step is conducted with a flash lamp annealing apparatus.

As shown in FIG. 1D, the flash lamp annealing apparatus has a hot plate 16 and a flash lamp light source 17.

The hot plate 16 is a metal plate incorporating a heating resistor. The temperature of the hot plate 16 is controlled by a thermocouple thermometer embedded in the hot plate 16.

The flash lamp light source 17 has a plurality of lamps facing the wafer 10. The lamps are lamps containing an inert gas, such as Xe gas.

The flash lamp light source 17 is designed to emit light 18 having a pulse width of about 0.1 milliseconds to 100 milliseconds. The energy density of the light 18 emitted from the flash lamp light source 17 is 25 J/cm² on the upper surface of the wafer 10, for example.

In a heat treatment in the FLA step, first, the wafer 10 is mounted on the hot plate 16 as shown in FIG. 1D and then preliminarily heated to a temperature of about 300° C. to 600° C. Then, the upper surface of the wafer 10 preliminarily heated is heated by the light 18 emitted from the flash lamp light source 17. More specifically, the upper surface of the wafer 10 is heated by irradiating the wafer 10 with the light 18 in an atmosphere of an inert gas, such as nitrogen gas and argon gas.

By the heat treatment described above, the impurity in an ion implantation layer is activated, and an impurity diffusion layer 19 is formed.

Now, effects of this embodiment will be discussed by comparison with a conventional method.

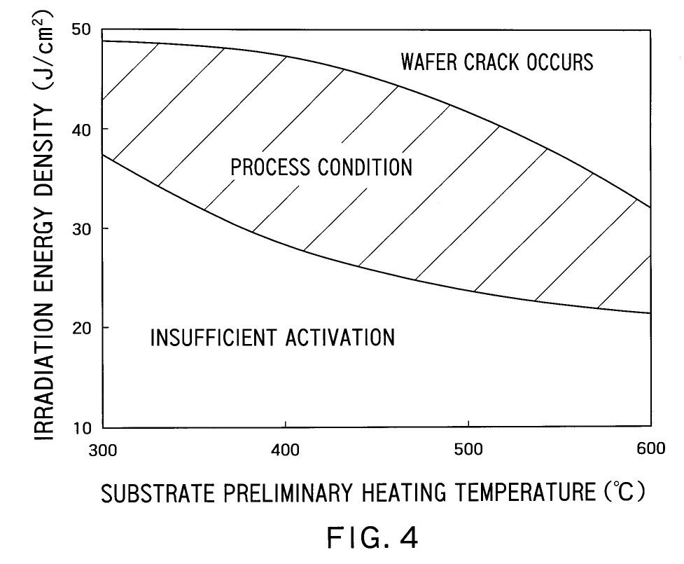

FIG. 4 is a graph showing a process margin for a wafer crack in the FLA step in the method of manufacturing a semiconductor device according to the embodiment 1.

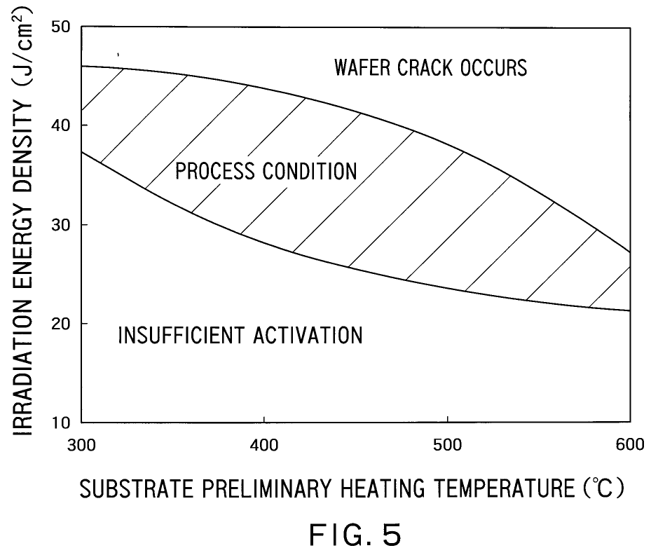

On the other hand, FIG. 5 is a graph showing a process margin for a wafer crack in the FLA step in a conventional method of manufacturing a semiconductor device.

As shown in FIGS. 4 and 5, according to this embodiment, the irradiation energy density and the preliminary heating temperature at which treatment can be conducted without causing a wafer crack are high compared with the conventional method. In other words, according to this embodiment, the process window is expanded.

In the FLA process, the upper surface of the wafer is instantaneously heated to a high temperature. However, the temperature of the lower part of the wafer does not rise with the temperature of the upper surface. Therefore, a stress occurs due to expansion and deformation of the upper part of the wafer. However, the thermal expansion of the lower part is smaller than that of the upper part, and therefore, the lower part does not expand at the same rate as the upper part. As a result, the stress in the wafer increases. Thus, it is considered that, if damage exists in the edge part of the wafer, and the strength of the wafer is reduced as in the case of the conventional method, the increased stress causes fracture of the wafer.

According to this embodiment, since the damaged superficial layer is removed from the bevel surfaces and the side surface of the wafer by polishing, reduction of the strength of the wafer is prevented. Therefore, it can be considered that the process window of the method of manufacturing a semiconductor device according to this embodiment is expanded as shown in FIG. 4.

As described above, according to the method of manufacturing a semiconductor device according to this embodiment, the FLA process can be conducted while reducing the possibility of a wafer crack.

### EMBODIMENT 2

In the embodiment 1, there has been described an example of a method of removing damage existing in a superficial layer of an outer perimeter (an upper surface, bevel surfaces and a side surface of an edge part) of a semiconductor substrate before a heat treatment step in which the semiconductor substrate is heated by light irradiation.

In an embodiment 2, there will be described an example of a method of removing damage existing in a superficial layer of an outer perimeter (an upper surface, bevel surfaces and a side surface of an edge part) of a semiconductor substrate after a thermal step in which the semiconductor substrate is heated by light irradiation.

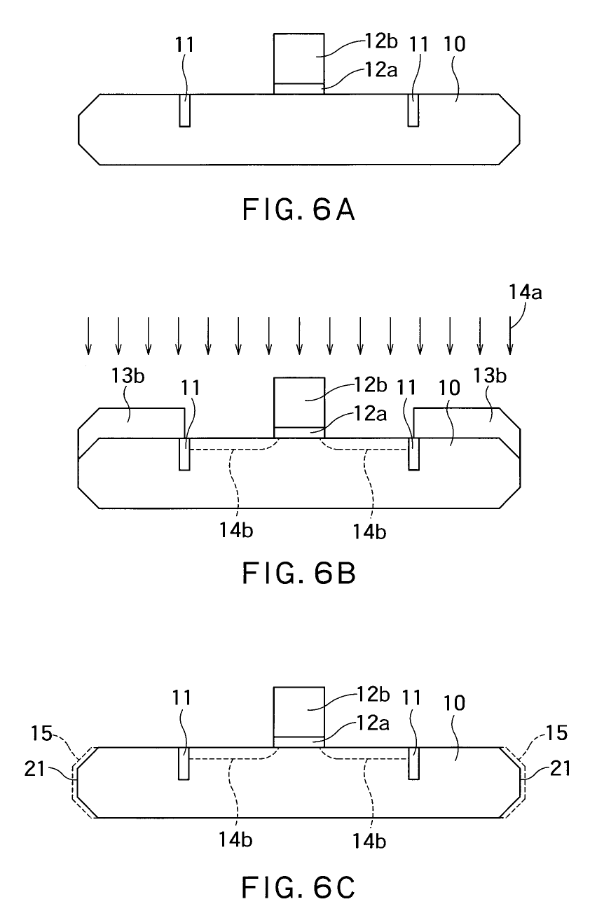

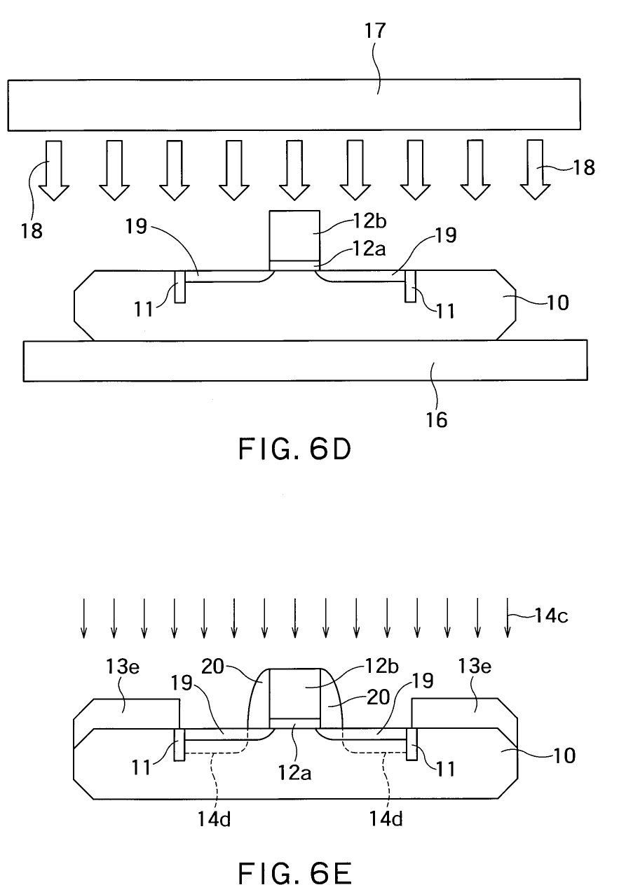

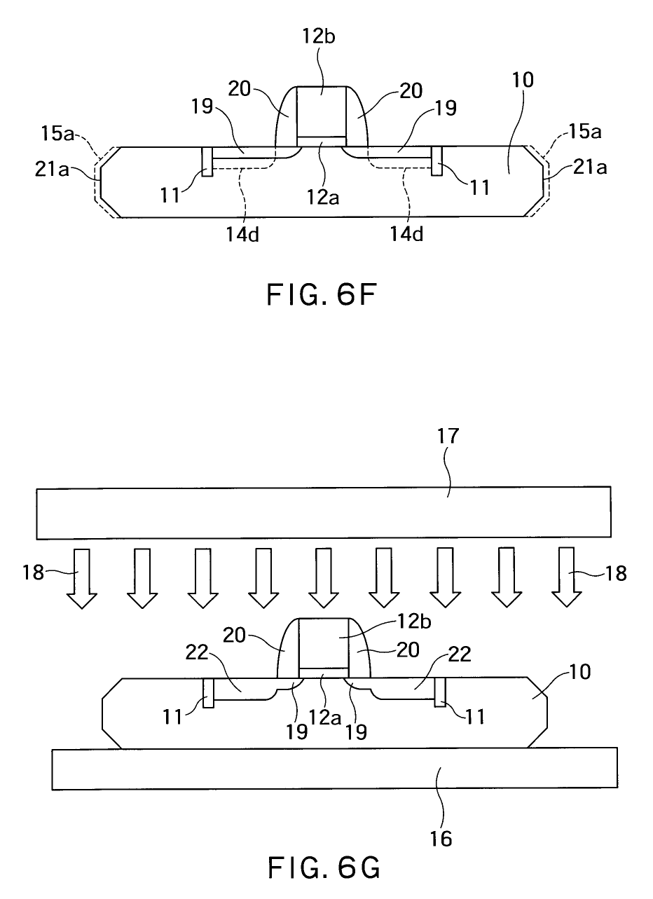

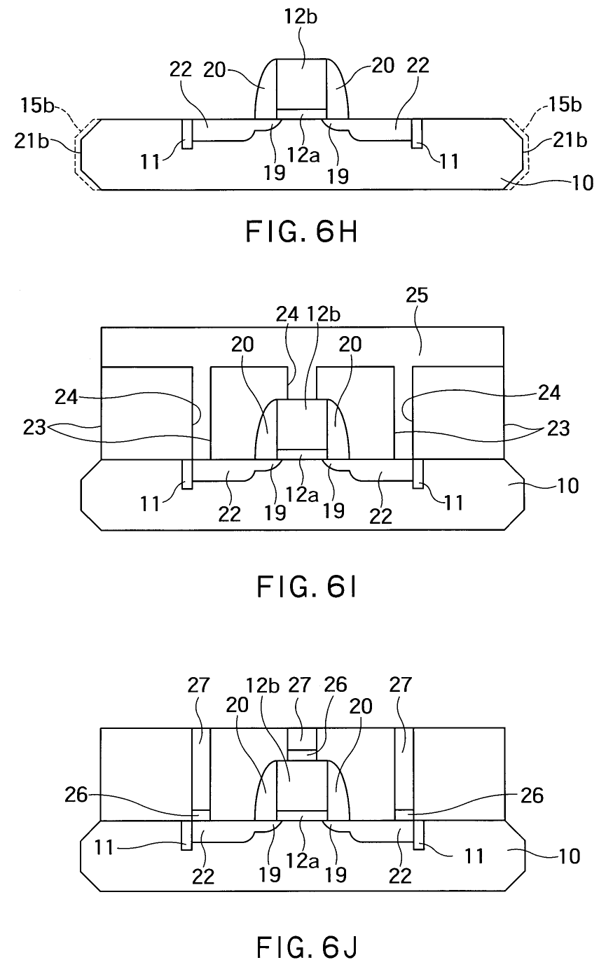

FIGS. 6A to 6J are schematic diagrams showing different steps in a method of manufacturing a semiconductor device according to the embodiment 2 of the present invention, which is an aspect of the present invention. In FIGS. 6A to 6J, the same reference numerals as those in FIGS. 1A to 1D denote the same parts as those in the embodiment 1. The steps shown in FIGS. 6A to 6D are the same as the steps shown in FIGS. 1A to 1D, respectively.

As in the embodiment 1, first, as shown in FIG. 6A, an device isolation region 11, a gate insulating film 12a and a gate electrode 12b are formed on a wafer 10 of silicon or the like, which is a semiconductor substrate, by a well-known method.

Then, as shown in FIG. 6B, as in the embodiment 1, using the gate electrode 12b and a resist film 13b having a desired pattern formed by photolithography as a mask, an impurity ion 14a is ion-implanted into a source/drain extension region 14b formed in an upper surface of the wafer 10. After the ion implantation, the resist film 13b is removed by peeling off.

Then, as shown in FIG. 6C, as in the embodiment 1, an upper surface, bevel surfaces and a side surface of an edge part of the wafer 10 are polished to remove a superficial layer thereof having a thickness of about 30 μm to 100 μm. Thus, a defect, a crack or the like formed in the superficial layer of the edge part of the wafer 10 can be removed.

Then, a FLA step is conducted with a flash lamp annealing apparatus.

As shown in FIG. 6D, as in the embodiment 1, in a heat treatment in the FLA step, first, the wafer 10 is mounted on a hot plate 16 and preliminarily heated to a temperature of about 300° C. to 600° C. Then, the upper surface of the wafer 10 preliminarily heated is heated by light 18 emitted from a flash lamp light source 17. More specifically, the upper surface of the wafer 10 is heated by irradiating the wafer 10 with the light 18 in an atmosphere of an inert gas, such as nitrogen gas and argon gas.

By the heat treatment described above, the impurity in an ion implantation layer is activated, and an impurity diffusion layer 19 is formed. This heat treatment can also be another heat treatment, such as RTA.

Then, as shown in FIG. 6E, a gate sidewall insulating film (spacer) 20 is formed by a well-known method. Then, using the gate sidewall insulating film 20 and a resist film 13e having a desired pattern formed by photolithography as a mask, an impurity ion 14c is implanted into the upper surface of the wafer 10. After the ion implantation, the resist film 13e is removed by peeling off. In this way, a region 14d in which the impurity is ion-implanted is formed. The region 14d constitutes a source/drain region at the end of the process.

Then, as in the embodiment 1, as shown in FIG. 6F, the upper surface, the bevel surfaces and the side surface of the edge part of the wafer 10 are polished to remove a superficial layer thereof having a thickness of about 30 μm to 100 μm. Thus, a defect, a crack or the like formed in the superficial layer of the edge part of the wafer 10 by the heat treatment shown in FIG. 6D or the like can be removed.

In FIG. 6F, the dotted line 15a (corresponding to the solid line 21 described above) indicates the surface of the edge part of the wafer 10 yet to be polished (before the superficial layer is removed). The solid line 21a indicates the surface of the edge part of the wafer 10 polished (after the superficial layer is removed).

Then, as shown in FIG. 6G, as in the step shown in FIG. 6D, the wafer 10 is heated by FLA. As a result, the impurity ion 14c implanted in the region 14d to constitute the source/drain region is activated, and a source/drain region 22 is formed in the upper surface of the wafer 10.

Then, as in the embodiment 1, as shown in FIG. 6H, the upper surface, the bevel surfaces and the side surface of the edge part of the wafer 10 are polished to remove a superficial layer thereof having a thickness of about 30 μm to 100 μm. Thus, a defect, a crack or the like formed in the superficial layer of the edge part of the wafer 10 by the heat treatment shown in FIG. 6G or the like can be removed.

In FIG. 6H, the dotted line 15b (corresponding to the solid line 21a described above) indicates the surface of the edge part of the wafer 10 yet to be polished (before the superficial layer is removed). The solid line 21b indicates the surface of the edge part of the wafer 10 polished (after the superficial layer is removed).

Then, as shown in FIG. 6I, an interlayer insulating film 23 is deposited on the entire upper surface of the wafer by CVD or the like. Then, contact holes 24 are formed in the source/drain region and the gate region by a well-known method.

Then, a metal film 25 of cobalt (Co) or the like is deposited on the upper surface of the wafer by sputtering or the like. Then, RTA or other annealing (silicidation annealing) of the wafer is conducted at a temperature of about 450° C. to 550° C. for 30 to 60 seconds in an atmosphere of an inert gas, such as nitrogen gas.

By the silicidation annealing, as shown in FIG. 6J, metal silicide layers 26 having low resistance are formed on the upper surfaces in the contact holes of the source/drain region and the gate region.

Then, any unreacted metal film is removed by immersion in an acid liquid, for example. Then, a metal, such as tungsten, is embedded in the contact holes to form plugs 27 on the metal silicide layers. The plugs 27 enable electrical connection to the source/drain region and the gate region.

As described above, since the superficial layer is removed by polishing from the upper surface, the bevel surfaces and the side surface of the edge part of the wafer after the FLA process (FIG. 6H), damage occurring in the FLA process is also removed. Therefore, the strength of the wafer is hardly reduced.

Therefore, the resistance to the thermal stress that occurs in the wafer in the thermal step after the FLA step does not decrease. Therefore, the frequency of wafer fractures is substantially reduced.

As described above, in this embodiment, the superficial layer of the edge part of the wafer is removed (FIGS. 6C and 6F) before the two heat treatments (FIGS. 6D and 6G). For example, if the temperature of the second heat treatment is higher than the temperature of the first heat treatment, removal of the superficial layer of the edge part of the wafer conducted before the second heat treatment (FIG. 6F) is particularly important in order to reduce damage to the edge part of the wafer during the second heat treatment.

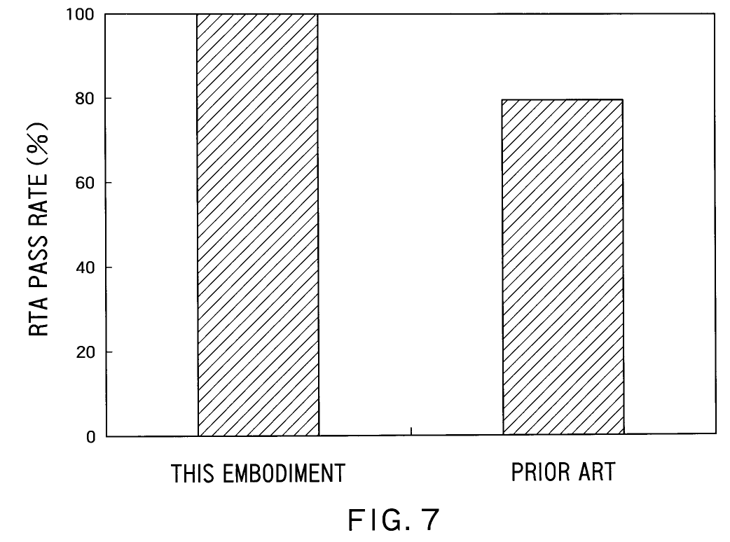

FIG. 7 is a graph showing the frequencies of fractures of wafers processed by the method of manufacturing a semiconductor device according to this embodiment and wafers processed by a conventional method of manufacturing a semiconductor device in the silicidation annealing step.

FIG. 7 shows the RTA pass rate, which indicates the percentage of wafers that pass the RTA process without being fractured, in a case where 240 wafers are processed by the method of manufacturing a semiconductor device according to this embodiment and subjected to the RTA process in the silicidation annealing step. In addition, for comparison, FIG. 7 shows the RTA pass rate in a case where 240 wafers are subjected to the RTA process without removing the superficial layer from the side surface and the bevel surfaces of the wafers after the FLA step.

As shown in FIG. 7, in the case where the superficial layer is not removed from the side surface and the bevel surfaces of the wafer after the FLA step as in the conventional method, the percentage of wafers that pass the RTA process without being fractured was about 80%.

On the other hand, according to the method of manufacturing a semiconductor device according to this embodiment, no wafer fracture occurred.

Thus, it can be said that, according to the method of manufacturing a semiconductor device according to this embodiment, the frequency of fractures of wafers in the thermal step after the FLA step is dramatically reduced.

As described above, according to the method of manufacturing a semiconductor device according to this embodiment, the FLA process can be conducted while reducing the frequency of wafer fractures.

### EMBODIMENT 3

In the embodiment 1, there has been described an example of a method of removing damage existing in a superficial layer of an outer perimeter (an upper surface, bevel surfaces and a side surface of an edge part) of a semiconductor substrate before a heat treatment step in which the semiconductor substrate is heated by light irradiation.

In an embodiment 3, there will be described an example of a method of removing damage existing in a superficial layer of an outer perimeter (at least a lower surface and a lower bevel surface of an edge part) of a semiconductor substrate after a thermal step in which the semiconductor substrate is heated by light irradiation.

A method of manufacturing a semiconductor device according to this embodiment will be described. In the following, for the sake of simplicity, a configuration of one MOS transistor will be particularly described.

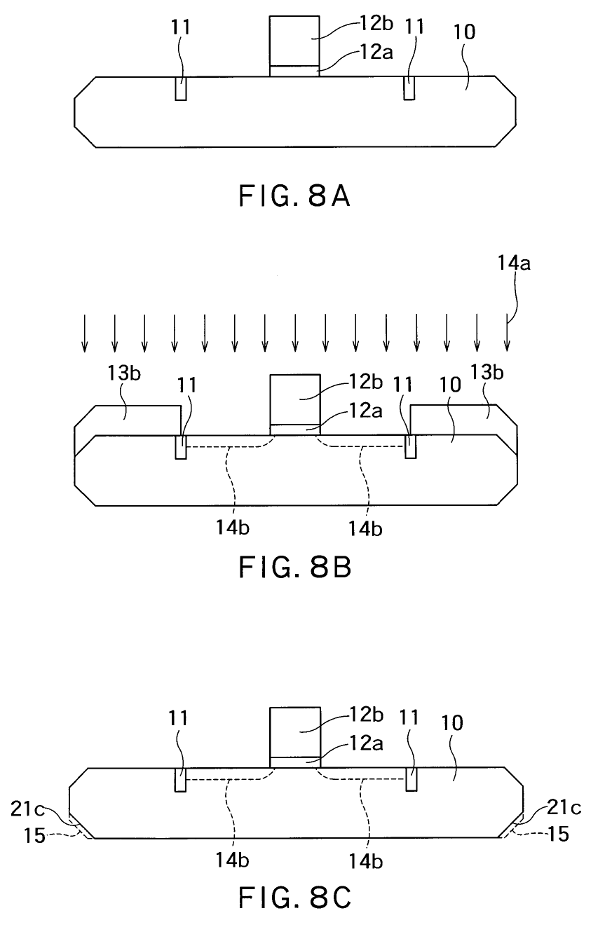

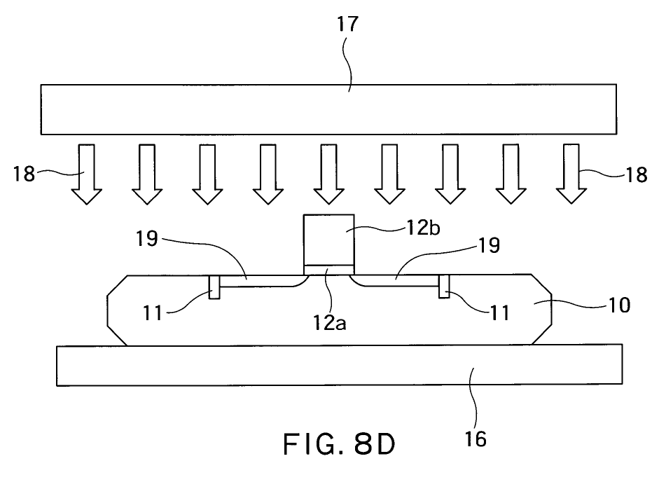

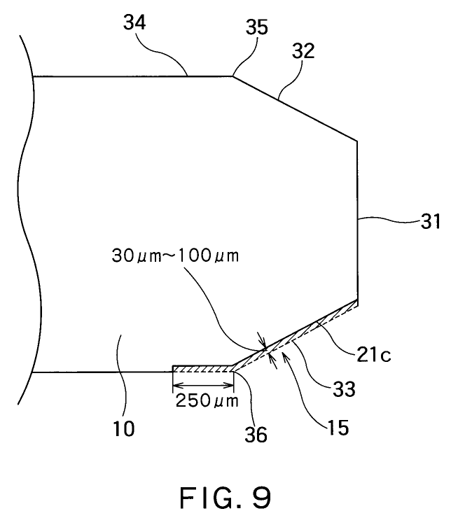

FIGS. 8A to 8D are schematic diagrams showing different steps in the method of manufacturing a semiconductor device according to the embodiment 3 of the present invention, which is an aspect of the present invention. FIG. 9 is a schematic enlarged cross-sectional view of an edge part of a wafer polished in the step shown in FIG. 8C. In these drawings, the same reference numerals as those in the embodiment 1 denote the same parts as those in the embodiment 1.

First, as shown in FIG. 8A, an device isolation region 11, a gate insulating film 12a and a gate electrode 12b are formed on a wafer 10 of silicon or the like, which is a semiconductor substrate, by a well-known method. The wafer 10 is selected from among a bulk single crystal silicon wafer, an epitaxial wafer and a SOI wafer, for example.

Then, as shown in FIG. 8B, using the gate electrode 12b and a resist film 13b having a desired pattern formed by photolithography as a mask, an impurity ion 14a is ion-implanted into a source/drain extension region 14b formed in an upper surface of the wafer 10. After the ion implantation, the resist film 13b is removed by peeling off.

Then, as shown in FIG. 8C, a lower surface and a lower bevel surface of an edge part of the wafer 10 are polished to remove a superficial layer extending about 100 μm to 400 μm (250 μm in FIG. 9) inwardly from a boundary 36 between the lower bevel surface and the lower surface, for example. In this step, the superficial layer removed has a depth of at least 10 μm (preferably about 30 μm to 100 μm as in the embodiments described above).

In FIG. 8C, the dotted line 15 indicates the surface of the edge part of the wafer 10 yet to be polished (before the superficial layer is removed). The solid line 21c indicates the surface of the edge part of the wafer 10 polished (after the superficial layer is removed).

In this way, a defect, a crack or the like formed in the superficial layer of the lower surface and the lower bevel surface of the edge part of the wafer 10 can be removed.

The edge part of the wafer 10 can be polished by a commonly known method, as in the embodiments described above. For example, the lower surface of the wafer 10 is fixed to a base material by vacuum chucking. Then, the wafer 10 is pressed against a polishing pad while rotating the wafer 10 along with the base material. In this process, a polishing liquid containing fine abrasive grains dispersed therein is supplied to the part of the wafer 10 in contact with the polishing pad. Thus, the superficial layer of the edge part of the wafer 10 in contact with the polishing pad can be removed by polishing.

The thickness of the part of the wafer removed by polishing can be estimated from the length of polishing time if the relationship between the polishing time and the amount of shavings is previously determined by measurement. In the determination of the relationship, the amount of shavings can be estimated by observing the difference between the shape of the cross section of the wafer before polishing and that after polishing with an electron microscope or the like.

As shown in FIG. 9, the wafer 10 has a side surface 31, a bevel surface 32 and a bevel surface 33 at the edge part thereof.

In FIG. 9, the shaded part indicates the superficial layer of the edge part of the wafer 10 that is removed by polishing.

Thus, damage, such as a flaw, a crack and a crystal defect, that can exist in the lower surface and the lower bevel surface 33 of the edge part can also be removed. Therefore, FLA can be conducted without causing degradation of the strength of the wafer 10 due to such damage.

In some cases, an extremely fine stripe pattern can be formed on the polished surface of the edge part of the wafer 10. This pattern is a trace of an abrasive grain. However, the trace is an extremely shallow groove, and therefore it can be considered that the trace have no effect on the strength of the wafer 10.

Then, a FLA step is conducted with a flash lamp annealing apparatus.

As shown in FIG. 8D, the flash lamp annealing apparatus has a hot plate 16 and a flash lamp light source 17.

The hot plate 16 is a metal plate incorporating a heating resistor. The temperature of the hot plate 16 is controlled by a thermocouple thermometer embedded in the hot plate 16.

The flash lamp light source 17 has a plurality of lamps facing the wafer 10. The lamps are lamps containing an inert gas, such as Xe gas.

The flash lamp light source 17 is designed to emit light 18 having a pulse width of about 0.1 milliseconds to 100 milliseconds. The energy density of the light 18 emitted from the flash lamp light source 17 is 25 J/cm² on the upper surface of the wafer 10, for example.

In a heat treatment in the FLA step, first, the wafer 10 is mounted on the hot plate 16 as shown in FIG. 8D and then preliminarily heated to a temperature of about 300° C. to 600° C. Then, the upper surface of the wafer 10 preliminarily heated is heated by the light 18 emitted from the flash lamp light source 17. More specifically, the upper surface of the wafer 10 is heated by irradiating the wafer 10 with the light 18 in an atmosphere of an inert gas, such as nitrogen gas and argon gas.

By the heat treatment described above, the impurity in an ion implantation layer is activated, and an impurity diffusion layer 19 is formed.

Now, effects of this embodiment will be discussed by comparison with a conventional method.

In the FLA process, the upper surface of the wafer is instantaneously heated to a high temperature. However, the temperature of the lower part of the wafer does not rise with the temperature of the upper surface. Therefore, a stress occurs due to expansion and deformation of the upper part of the wafer. However, the thermal expansion of the lower part is smaller than that of the upper part, and therefore, the lower part does not expand at the same rate as the upper part. As a result, the stress in the wafer increases. Thus, it is considered that, if damage exists in the edge part of the wafer, and the strength is reduced as in the case of the conventional method, the increased stress causes fracture of the wafer.

According to this embodiment, since the damaged superficial layer is removed from the lower surface and the lower bevel surface of the edge part of the wafer by polishing, reduction of the strength of the wafer is prevented.

As described above, according to the method of manufacturing a semiconductor device according to this embodiment, the FLA process can be conducted while reducing the possibility of a wafer crack.

In the embodiments described above, there have been described cases where the superficial layer of the edge part of the wafer is removed by polishing. However, the superficial layer of the edge part of the wafer can also be removed by etching with an acid or alkaline liquid, cutting or the like.

In addition, in the embodiments described above, there have been described cases where a xenon flash lamp is used as a light source for the FLA in which the wafer is heated by light having a pulse width of 0.1 milliseconds to 100 milliseconds. However, the present invention is not limited to the xenon flash lamp, and flash lamps using other kinds of inert gas, mercury, or hydrogen, or an arc discharge lamp can also be used as a light source, for example. Alternatively, lasers having a wavelength of 500 nm to 11 μm, such as an excimer laser, an Ar laser, an N₂ laser, a YAG laser, a titanium-sapphire laser, a CO laser and a CO₂ laser, can be used as a light source.

What is claimed is:

1. A method of manufacturing a semiconductor device that involves a heat treatment of a semiconductor substrate, comprising:
removing a superficial layer from an upper surface of an edge part of said semiconductor substrate, a bevel surface of the edge part of said semiconductor substrate and a side surface of the edge part of said semiconductor substrate; and
conducting the heat treatment of said semiconductor substrate by irradiating said semiconductor substrate with light having a pulse width of 0.1 milliseconds to 100 milliseconds from a light source after said superficial layer is removed.

2. The method of manufacturing a semiconductor device according to claim 1, wherein the thickness of said superficial layer removed falls within a range of 30 μm to 100 μm.

3. The method of manufacturing a semiconductor device according to claim 1, wherein said superficial layer of the upper surface of said edge part is removed over a region extending 3 mm from a boundary between the upper surface and the bevel surface of said edge part of said semiconductor substrate.

4. The method of manufacturing a semiconductor device according to claim 2, wherein said superficial layer of the upper surface of said edge part is removed over a region extending 3 mm from a boundary between the upper surface and the bevel surface of said edge part of said semiconductor substrate.

5. The method of manufacturing a semiconductor device according to claim 1, wherein said light source is a xenon flash lamp or a laser having a wavelength of 500 nm to 11 μm.

6. The method of manufacturing a semiconductor device according to claim 2, wherein said light source is a xenon flash lamp or a laser having a wavelength of 500 nm to 11 μm.

7. The method of manufacturing a semiconductor device according to claim 3, wherein said light source is a xenon flash lamp or a laser having a wavelength of 500 nm to 11 μm.

8. A method of manufacturing a semiconductor device that involves a heat treatment of a semiconductor substrate, comprising:
conducting the heat treatment of said semiconductor substrate by irradiating said semiconductor substrate with light having a pulse width of 0.1 milliseconds to 100 milliseconds from a light source; and
removing a superficial layer from an upper surface of an edge part of said semiconductor substrate, a bevel surface of the edge part of said semiconductor substrate and a side surface of the edge part of said semiconductor substrate after the heat treatment of said semiconductor substrate is conducted.

9. The method of manufacturing a semiconductor device according to claim 8, wherein the thickness of said superficial layer removed falls within a range of 30 μm to 100 μm.

10. The method of manufacturing a semiconductor device according to claim 8, wherein said superficial layer of the upper surface of said edge part is removed over a region extending 3 mm from a boundary between the upper surface and the bevel surface of said edge part of said semiconductor substrate.

11. The method of manufacturing a semiconductor device according to claim 9, wherein said superficial layer of the upper surface of said edge part is removed over a region extending 3 mm from a boundary between the upper surface and the bevel surface of said edge part of said semiconductor substrate.

12. The method of manufacturing a semiconductor device according to claim 8, wherein said light source is a xenon flash lamp or a laser having a wavelength of 500 nm to 11 μm.

13. The method of manufacturing a semiconductor device according to claim 9, wherein said light source is a xenon flash lamp or a laser having a wavelength of 500 nm to 11 μm.

14. The method of manufacturing a semiconductor device according to claim 10, wherein said light source is a xenon flash lamp or a laser having a wavelength of 500 nm to 11 μm.

15. A method of manufacturing a semiconductor device that involves a heat treatment of a semiconductor substrate, comprising:
removing a superficial layer from a lower surface of an edge part of said semiconductor substrate and a lower bevel surface of the edge part of said semiconductor substrate; and
conducting the heat treatment of said semiconductor substrate by irradiating said semiconductor substrate with light having a pulse width of 0.1 milliseconds to 100 milliseconds from a light source after said superficial layer is removed.

16. The method of manufacturing a semiconductor device according to claim 15 wherein said light source is a xenon flash lamp or a laser having a wavelength of 500 nm to 11 μm.
